(19) United States
(12) Patent Application Publication
(10) Pub. No.: US 2020/0168133 A1
(43) Pub. Date: May 28, 2020

(54) OLED DISPLAY DEVICE

(71) Applicant: SHENZHEN CHINA STAR OPTOELECTRONICS SEMICONDUTOR DISPLAY TECHNOLOGY CO., LTD., Shenzhen, Guangdong (CN)

(72) Inventors: Taijiun HWANG, Shenzhen, Guangdong (CN); Guohui LIU, Shenzhen, Guangdong (CN)

(21) Appl. No.: 16/091,295

(22) PCT Filed: Sep. 13, 2018
(86) PCT No.: PCT/CN2018/105581

§ 371 Date: Oct. 4, 2018

(30) Foreign Application Priority Data
Apr. 8, 2018 (CN) 201810308354.0

(51) Int. Cl. G09F 9/302; G09G 3/3208; G09F 9/30

(52) U.S. Cl. CPC G09F 9/3026; G09G 2300/026; G09F 9/301; G09G 3/3208

(57) ABSTRACT

The present invention teaches an OLED display device having a spherical shape and a spherical display area. The OLED display device includes multiple display modules, a physical frame, and a driving system. Each display module is a flexible OLED display panel. These display modules are curved to attach on the spherical surface of the physical frame. The display areas of these display modules therefore are tiled together to form the spherical display area of the OLED display device. The driving system is configured inside the physical frame for driving the display modules. Compared to the existing spherical LED panel or optical projection panel, the OLED display device has advantages such as high resolution and superior color gamut.

### FIELD OF THE INVENTION

The present invention is generally related to the field of display technology, and more particularly to a tiled organic light emitting diode (OLED) display device.

### BACKGROUND OF THE INVENTION

Modern people rely more and more on visual information. The purpose of display technologies is exactly to present visual information through useful, rich, and colorful texts, graphs, and images by appropriately adjusting light characteristics such as brightness, wavelength, direction, etc.

Currently, display panels, due to production techniques, are usually made into a square or rectangular shape. Large display panels are often formed by tiling multiple smaller and rectangular display panels. However, there are times when display panels of a special shape, e.g., a spherical shape, a parallelogram shape, or other polygonal shape, are required, Among them, the spherical display panels are most difficult to produce. Usually multiple polygonal display panels are tiled together to form the spherical display panel.

Spherical display panels, capable of providing viewers with 360-degree viewing experience, have already been an eye-catching product. Existing spherical display panels usually adopt light emitting diode (LED) or optical projection techniques. The LED spherical panels are usually tiled dot-matrix panels.

Organic light emitting diode (OLED) is a promising display technology. It is considered as the “dream” display device by the industry due to its superior performance, especially its self-illumination, low driving voltage, high lighting efficiency, simple structure, ultra-thin thickness, short response time, wide viewing angle, lower power consumption, and the capability to fulfill flexible display, Compared to LED displays and optical projection displays, OLED has high resolution and enhanced color gamut due to its lighting characteristics.

### SUMMARY OF THE INVENTION

An objective of the present invention is to teach an OLED display device where flexible OLED display panels are curved to attach on the spherical surface of a physical frame. These OLED display panels therefore are tiled together to form the spherical display area. The OLED display device has advantages such as high resolution and superior color gamut.

To achieve the objective, the present invention teaches an OLED display device having a spherical shape and a spherical display area. The OLED display device includes two or more display modules, a physical frame, and a driving system.

Each display module is a flexible OLED display panel having a display area and a non-display area outside the display area. A driving unit is configured in each non-display area.

The physical frame has a spherical shape. The two or more display modules are curved and attached to the surface of the physical frame. The display areas of the two or more display modules jointly form the spherical display area of the OLED display device.

The driving system is housed inside the physical frame and is connected to the driving units of the two or more display modules so as to drive the display modules to display pictures.

The two or more display modules have display areas of identical or different shapes. The shape may be triangular, rectangular, pentagonal, hexagonal, or a shape with curved edges.

In an embodiment, the OLED display device includes two display modules, whose display areas have an identical dumb-bell shape. The two display areas are tiled together to jointly form the spherical display area of the OLED display device on the surface of the physical frame like the surface of a tennis ball.

The OLED display device has more than two display modules, Some of the display modules have display areas of a pentagonal shape, and the others have display areas of a hexagonal shape. The pentagonal and hexagonal shapes have an identical side length.

In another embodiment, the OLED display device includes 32 display modules. 12 of them have pentagon-shaped display areas and the others have hexagon-shaped display areas. These 32 display areas are tiled together on the surface of the physical frame 20 into the spherical display area like the surface of a soccer ball.

The OLED display device has more than two display modules. These display modules have display areas of an identical diamond shape. These display areas are tiled together on the surface of the physical frame into the spherical display area like the surface of a watermelon.

The physical frame includes a spherical wall and a hollow space surrounded by the spherical wall. The spherical wall has slits and the non-display area of each display module is bent into the inside of the physical frame through a slit. The driving system is configure inside the hollow space.

The slits penetrate the spherical wall, and the non-display areas of the display modules are bended and embedded into the hollow space through the slits.

The slits are separated from the hollow space by the spherical wall. The non-display areas of the display modules are bended and stored in the spherical wall through the slits.

The driving unit of each display module is configured to a side of the display area.

The driving unit of each display module includes a source driving unit and a gate driving unit.

The driving system provides driving signals to the driving units of the two or more display modules. Each driving unit receives the driving signals and drives the display module to display pictures.

The present invention teaches another OLED display device having a spherical shape and a spherical display area. The OLED display device includes two or more display modules, a physical frame, and a driving system.

wherein each display module is a flexible OLED display panel having a display area and a non-display area outside the display area; a driving unit is configured in each non-display area;

the physical frame has a spherical shape; the two or more display modules are curved and attached to the surface of the physical frame; the display areas of the two or more display modules jointly form the spherical display area of the OLED display device; and

the driving system is housed inside the physical frame and is connected to the driving units of the two or more display modules so as to drive the display modules to display pictures;

the two or more display modules have display areas of identical or different shapes; the shape is one of a triangular, rectangular, pentagonal, hexagonal shape, or a shape with curved edges;

the physical frame comprises a spherical wall and a hollow space surrounded by the spherical wall; the spherical wall has slits and the non-display area of each display module is bent into the inside of the physical frame through a slit; the driving system is configure inside the hollow space;

the slits penetrate the spherical wall, and the non-display areas of the display modules are bended and embedded into the hollow space through the slits;

the driving unit of each display module is configured to a side of the display area;

the driving unit of each display module comprises a source driving unit and a gate driving unit;

the driving system provides driving signals to the driving units of the two or more display modules; and each driving unit receives the driving signals and drives the display module to display pictures.

The present invention has the following advantages. The OLED display device of the present invention has a spherical shape and a spherical display area. The OLED display device includes multiple display modules, a physical frame, and a driving system. Each display module is a flexible OLED display panel. These display modules are curved to attach on the spherical surface of the physical frame.

The display areas of these display modules therefore are tiled together to form the spherical display area of the OLED display device. The driving system is configured inside the physical frame for driving the display modules. Compared to the existing spherical LED panel or optical projection panel, the OLED display device has advantages such as high resolution and superior color gamut.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a schematic diagram showing how an OLED display device according to a first embodiment of the present invention is assembled,

FIG. 2 is a schematic diagram showing how an OLED display device according to a second embodiment of the present invention is assembled.

FIG. 3 is a schematic diagram showing how an OLED display device according to a third embodiment of the present invention is assembled.

FIG. 4 is a schematic sectional diagram showing a physical frame in an OLED display device of the present invention,

FIG. 5 is a schematic sectional diagram showing another physical frame in an OLED display device of the present invention.

### DETAILED DESCRIPTION OF PREFERRED EMBODIMENTS

The following descriptions for the respective embodiments are specific embodiments capable of being implemented for illustrations of the present invention with referring to appended figures.

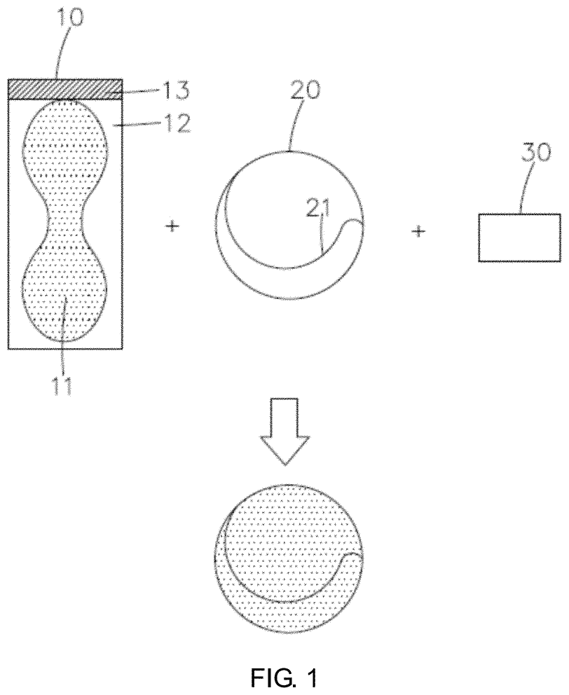

As shown in FIG. 1, an OLED display device according to a first embodiment of the present invention has a spherical shape and has a spherical display area. The OLED display device includes two or more display modules 10, a physical frame 20, and a driving system 30. Each display module 10 is a flexible OLED display panel having a display area 11 and a non-display area 12 outside the display area 11. A driving unit 13 is configured within the non-display area 12. The physical frame 20 has a spherical shape. The two or more display modules 10 are curved and attached to the surface of the physical frame 20. The display areas 11 of the two or more display modules 10 jointly form the spherical display area of the OLED display device. The driving system 30 is housed inside the physical frame 20 and is connected to the driving units 13 of the two or more display modules 10 so as to drive the display modules 10.

Specifically, the two or more display modules 10 have display areas of identical or different shapes. The shape may be triangular, rectangular, pentagonal, hexagonal, or a shape with curved edges.

Specifically, the driving unit 13 of each display module 10 includes a source driving unit and a gate driving unit.

Specifically, the driving system 30 provides driving signals to the driving units 13 of the two or more display modules 10. Each driving unit 13 receives the driving signals and drives the display module 10 to display pictures.

Specifically, the physical frame 20 has a hollow spherical shape, and includes a spherical wall 22 and a hollow space 23 surrounded by the spherical wall 22. The driving system 30 is configured in the hollow space 23. The spherical wall 22 has slits 21 and the non-display area 12 of each display module 10 is bent into the inside of the physical frame 20 through a slit 21. In this way, the surface of the physical frame 20 is completely covered by continuous display areas 11 of the display modules 10 without any non-display area 12, and the non-display areas 12 of the display modules 10 are all hidden inside the physical frame 20 by the display areas 11 of the display modules 10.

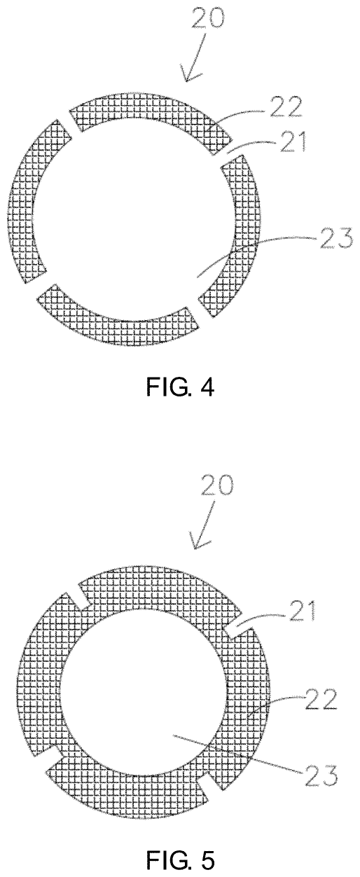

Specifically, as shown in FIG. 4, the slits 21 penetrate the spherical wall 22, and the non-display areas 12 of the display modules 10 are bended and embedded into the hollow space 23 through the slits 21.

Alternatively, as shown in FIG. 5, the slits 21 also may not run through the spherical wall 22, and the slits 21 are separated from the hollow space 23 by the spherical wall 22. The non-display areas 12 of the display modules 10 are bended and stored in the spherical wall 22 through the slits 21. Specifically, the hollow space 23 is a three-dimensional space, which may have a spherical shape as shown in FIGS. 4 and 5, and may be a cube, a cuboid, or an irregular three-dimensional shape, depending on product requirement.

Specifically, the driving unit 13 of each display module 10 is configured to a side of the display area 11.

Specifically, in the present embodiment, the OLED display device includes two display modules 10, whose display areas 11 have an identical dumb-bell shape. The two display areas 11 are tiled together to jointly form the spherical display area of the OLED display device on the surface of the physical frame 20 like the surface of a tennis ball.

The OLED display device uses flexible OLED display panels curved to attach on the spherical surface of the physical frame 20. These OLED display panels therefore are tiled together to form the spherical display area. Compared to the existing spherical LED panel or optical projection panel, the OLED display device has advantages such as high resolution and superior color gamut.

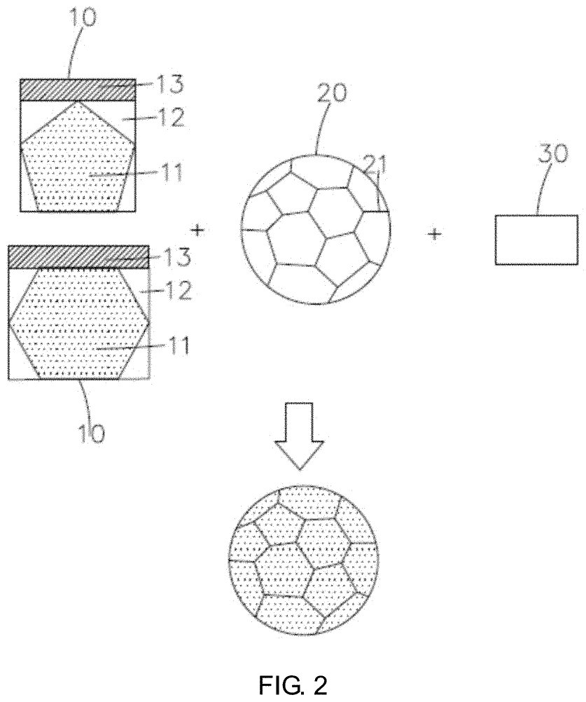

As shown in FIG. 2, a second embodiment of the OLED display device, compared to the first embodiment, has more than two display modules 10. Some of the display modules 10 have display areas 11 of a pentagonal shape, and the others have display areas 11 of a hexagonal shape. The pentagonal and hexagonal shapes have an identical side length.

Furthermore, the OLED display device of the present embodiment includes specifically 32 display modules 10, 12 of them have pentagon-shaped display areas 11 and the other 20 have hexagon-shaped display areas 11. These 32 display areas 11 are tiled together on the surface of the physical frame 20 into the spherical display area like the surface of a soccer ball. The other technical details of the present embodiment are identical to the first embodiment, and are omitted here.

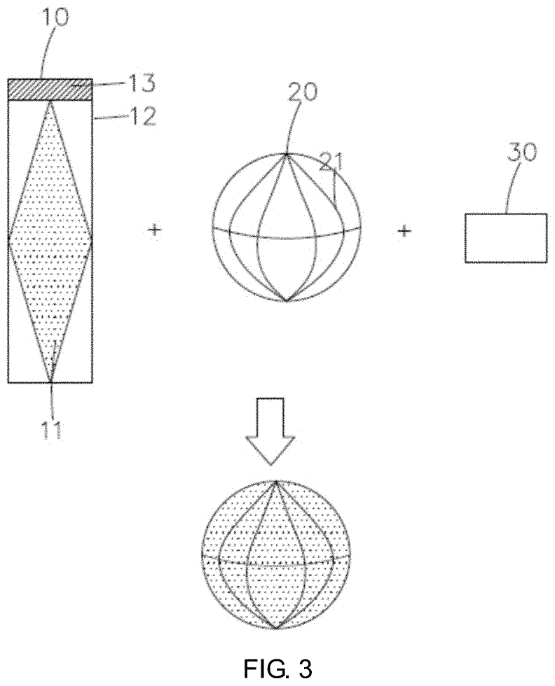

As shown in FIG. 3, a third embodiment of the OLED display device, compared to the first embodiment, has more than two display modules 10. These display modules 10 have display areas 11 of an identical diamond shape. These display areas 11 are tiled together on the surface of the physical frame 20 into the spherical display area like the surface of a watermelon. The number of display modules 10 required depends on the diameter of the physical frame 20. Other technical details of the present embodiment are identical to the first embodiment, and are omitted here.

As described above, the OLED display device of the present invention has a spherical shape and a spherical display area. The OLED display device includes multiple display modules, a physical frame, and a driving system. Each display module is a flexible OLED display panel. These display modules are curved to attach on the spherical surface of the physical frame. The display areas of these display modules therefore are tiled together to form the spherical display area of the OLED display device. The driving system is configured inside the physical frame for driving the display modules. Compared to the existing spherical LED panel or optical projection panel, the OLED display device has advantages such as high resolution and superior color gamut.

Above are embodiments of the present invention, which does not limit the scope of the present invention. Any equivalent amendments within the spirit and principles of the embodiment described above should be covered by the protected scope of the invention.

What is claimed is:

1. An organic light emitting diode (OLED) display device having a spherical shape and a spherical display area, comprising two or more display modules, a physical frame, and a driving system;
wherein each display module is a flexible OLED display panel having a display area and a non-display area outside the display area; a driving unit is configured in each non-display area;
the physical frame has a spherical shape; the two or more display modules are curved and attached to the surface of the physical frame; the display areas of the two or more display modules jointly form the spherical display area of the OLED display device; and
the driving system is housed inside the physical frame and is connected to the driving units of the two or more display modules so as to drive the display modules to display pictures.

2. The OLED display device according to claim 1, wherein the two or more display modules have display areas of identical or different shapes; and the shape is one of a triangular, rectangular, pentagonal, hexagonal shape, or a shape with curved edges.

3. The OLED display device according to claim 1, wherein there are two display modules, whose display areas have an identical dumb-bell shape; and the two display areas are tiled together to jointly form the spherical display area of the OLED display device on the surface of the physical frame like the surface of a tennis ball.

4. The OLED display device according to claim 1, wherein a plurality of the two or more display modules have display areas of a pentagonal shape; the other display modules have display areas of a hexagonal shape; and the pentagonal and hexagonal shapes have an identical side length.

5. The OLED display device according to claim 4, wherein there are 32 display modules; 12 of them have pentagon-shaped display areas and the other 20 have hexagon-shaped display areas; and the 32 display areas are tiled together on the surface of the physical frame into the spherical display area like the surface of a soccer ball.

6. The OLED display device according to claim 1, wherein the two or more display modules have display areas of an identical diamond shape; and the display areas are tiled together on the surface of the physical frame into the spherical display area like the surface of a watermelon.

7. The OLED display device according to claim 1, wherein the physical frame comprises a spherical wall and a hollow space surrounded by the spherical wall; the spherical wall has slits and the non-display area of each display module is bent into the inside of the physical frame through a slit; and the driving system is configure inside the hollow space.

8. The OLED display device according to claim 7, wherein the slits penetrate the spherical wall; and the non-display areas of the display modules are bended and embedded into the hollow space through the slits.

9. The OLED display device according to claim 7, wherein the slits are separated from the hollow space by the spherical wall; and the non-display areas of the display modules are bended and stored in the spherical wall through the slits.

10. The OLED display device according to claim 1, wherein the driving unit of each display module is configured to a side of the display area;
the driving unit of each display module comprises a source driving unit and a gate driving unit;
the driving system provides driving signals to the driving units of the two or more display modules; and each driving unit receives the driving signals and drives the display module to display pictures.

11. An OLED display device having a spherical shape and a spherical display area, comprising two or more display modules, a physical frame, and a driving system;
wherein each display module is a flexible OLED display panel having a display area and a non-display area outside the display area; a driving unit is configured in each non-display area;
the physical frame has a spherical shape; the two or more display modules are curved and attached to the surface of the physical frame; the display areas of the two or more display modules jointly form the spherical display area of the OLED display device; and
the driving system is housed inside the physical frame and is connected to the driving units of the two or more display modules so as to drive the display modules to display pictures;
the two or more display modules have display areas of identical or different shapes; the shape is one of a triangular, rectangular, pentagonal, hexagonal shape, or a shape with curved edges;
the physical frame comprises a spherical wall and a hollow space surrounded by the spherical wall; the spherical wall has slits and the non-display area of each display module is bent into the inside of the physical frame through a slit; the driving system is configure inside the hollow space;
the slits penetrate the spherical wall, and the non-display areas of the display modules are bended and embedded into the hollow space through the slits;
the driving unit of each display module is configured to a side of the display area;
the driving unit of each display module comprises a source driving unit and a gate driving unit;
the driving system provides driving signals to the driving units of the two or more display modules; and each driving unit receives the driving signals and drives the display module to display pictures.

12. The OLED display device according to claim 11, wherein there are two display modules, whose display areas have an identical dumb-bell shape; and the two display areas are tiled together to jointly form the spherical display area of the OLED display device on the surface of the physical frame like the surface of a tennis ball.

13. The OLED display device according to claim 11, wherein a plurality of the two or more display modules have display areas of a pentagonal shape; the other display modules have display areas of a hexagonal shape; and the pentagonal and hexagonal shapes have an identical side length.

14. The OLEO display device according to claim 13; wherein there are 32 display modules; 12 of them have pentagon-shaped display areas and the other 20 have hexagon-shaped display areas; and the 32 display areas are tiled together on the surface of the physical frame into the spherical display area like the surface of a soccer ball.

15. The OLEO display device according to claim 11, wherein the two or more display modules have display areas of an identical diamond shape; and the display areas are tiled together on the surface of the physical frame into the spherical display area like the surface of a watermelon.
